(19) United States
(12) Patent Application Publication
(10) Pub. No.: US 2015/0185142 A1
(43) Pub. Date: Jul. 2, 2015

(54) OLED Panel And Manufacturing Method Thereof And Method For Inspecting Packaging Effectiveness

(71) Applicant: Shenzhen China Star Optoelectonics Technology Co. Ltd., Shenzhen, Guangdong (CN)

(72) Inventors: Weijing Zeng, Shenzhen (CN); Yawei Liu, Shenzhen (CN)

(73) Assignee: Shenzhen China Star Optoelectronics Technology Co. Ltd., Shenzhen, Guangdong (CN)

(21) Appl. No.: 14/345,905

(22) PCT Filed: Jan. 13, 2014
(86) PCT No.: PCT/CN2014/070551

§ 371 Date: Mar. 19, 2014

(30) Foreign Application Priority Data
Dec. 30, 2013 (CN) 201310747014.5

(51) Int. Cl. G01N 21/3554; H01L 51/52; H01L 51/56

(52) U.S. Cl. CPC G01N 21/3554; H01L 51/56; H01L 51/5259; H01L 51/524

(57) ABSTRACT

The present invention provides OLED panel and a manufacturing method thereof and a method for inspecting packaging effectiveness, which use a hygroscopically expandable polymeric substance mixed in a metal compound salt to make a moisture-sensitive color change film. Since the hygroscopically expandable polymeric substance has better water absorbability, the moisture-sensitive color change film can serve as a desiccant of a sealed space of an OLED panel to extend the lifespan of the OLED panel and also, a portion of the metal compounds of the metal compound salt may react with moisture to turn into hydrates, causing color change so as to allow for determining packaging effectiveness according to the color change of the moisture-sensitive color change film after absorption of moisture thereby enabling easy determination of failure of the packaging through visual inspection and also enabling accurate measurement of water content of the sealed space of the OLED panel by using an infrared spectrophotometer to accurately determine the packaging effectiveness. Further, a manufacturing process of an OLED panel that involves such an inspection method is simple and can be easily carried out.

### BACKGROUND OF THE INVENTION

1. Field of the Invention

The present invention relates to the field of flat panel display, and in particular to an OLED panel and a manufacturing method thereof and a method for inspecting packaging effectiveness.

2. The Related Arts

A flat panel display has a variety of advantages, including thin device body, reduced power consumption, and being free of radiation and is widely used. Flat panel displays that are currently available generally include liquid crystal displays (LCDs) and organic light emitting displays (OLEDs).

The OLEDs, which show the characteristics of self-illumination, high brightness, wide view angle, high contrast, flexibility, and low energy consumption, attract wide attention to serve as the next-generation display measure that gradually substitute the conventional liquid crystal display devices for applications in mobile phone screens, computer monitors, and full-color television. The OLED displaying, which is different from the conventional way of displaying with LED, requires no backlight and adopts extremely thin layers of organic coatings and glass substrates. These organic materials become luminous when electricity is conducted therethrough. However, the organic materials can get readily oxidized with water and consequently, an OLED display panel, which is a display device manufactured based on the organic materials, must be subjected to extremely severe standard of packaging. For commercial applications, an OLED component must be capable of providing a lifetime exceeding or equal to 10,000 hours and meeting the packaging requirements of water permeability less than or equal to 10⁻⁶ g/m²/day and oxygen permeability less than or equal to 10⁻⁵ cc/m²/day (1 atm). This infers that packaging is the most important step of the entire process for manufacturing an OLED display panel and is the key factor that affects the product yield rate.

However, only a few methods are currently available to monitor packaging effectiveness achieved in most of the known OLED panel manufacture processes. One of the known processes is one that uses a desiccant to monitor the packaging effectiveness, of which the operation principle is that the desiccant, when absorbing humidity, gets expanded and photographing is applied to identify the surface areas of the desiccant at a preceding and a subsequent time point, whereby the sizes of the surface areas of the desiccant can be used to determine if the desiccant has been expanded and thus if there is any moisture invasion resulting from poor packaging of the OLED panel. The process is simple in principle bur suffers reliability issue. For example, when the desiccant absorbs moisture and gets expanded, the photographing measure only reflects the variation of the surface area thereof, but comparing the images obtained through photographing cannot reflect a minor volume change caused by the desiccant absorbing moisture. Thus, using the measure of desiccant absorbing moisture and getting expanded to inspect the effectiveness of packaging still needs further improvement.

### SUMMARY OF THE INVENTION

Thus, an object of the present invention is to provide an OLED panel, which has excellent packaging effectiveness and an extended lifespan.

Another object of the present invention is to provide a manufacturing method of an OLED panel, which has a simple process, and an OLED panel manufactured with the method has an extended lifespan, allows for effective inspection of the packaging effectiveness thereof to improve the yield rate of product.

A further object of the present invention is to provide a method for inspecting packaging effectiveness, which allows for easy determination of failure of package through visual inspection and effectively identifies contents of moisture existing in a sealed space of an OLED panel so as to accurately determine the packaging effectiveness of the OLED panel and can be easily carried out without causing adverse effects on the panel.

To achieve the objects, the present invention provides an OLED panel, which comprises: a substrate, a lid arranged opposite to the substrate, an OLED element arranged on the substrate, a moisture-sensitive color change film arranged on the lid, and an enclosing frame bonding the substrate and the lid 30 together, wherein the substrate, the lid, and the enclosing frame collectively define a sealed space therebetween. The OLED element and the moisture-sensitive color change film are hermetically enclosed in the sealed space. The moisture-sensitive color change film is made by mixing a hygroscopically expandable polymeric substance in a metal compound salt.

The OLED panel further comprises a liquid desiccant arranged in the sealed space.

The metal compound salt is composed of cobalt chloride, cobalt sulfate, copper sulfate, and cupric chloride. The substrate is an array substrate. The lid is made of glass. The enclosing frame is formed of frit or UV resin.

The present invention also provide a manufacturing method of an OLED panel, which comprises the following steps:

(1) providing a lid;

(2) coating frit on a circumferential edge of the lid and subjecting the frit to high temperature baking to form an enclosing frame;

(3) coating a moisture-sensitive color change film on the circumferential edge of the lid at a location inside the enclosing frame, followed by low temperature baking, wherein the moisture-sensitive color change film is made by mixing a hygroscopically expandable polymeric substance in a metal compound salt;

(4) coating UV resin on the enclosing frame;

(5) providing a substrate, wherein the substrate comprises an OLED element formed thereon; and

(6) aligning and bonding the substrate and the lid together with the UV resin and solidifying the UV resin and the enclosing frame to complete the manufacture of the OLED panel.

Step (4) further comprises coating a liquid desiccant on the lid and inside the enclosing frame. The metal compound salt is composed of cobalt chloride, cobalt sulfate, copper sulfate, and cupric chloride. The substrate is an array substrate and the lid is made of glass.

The present invention further provides a manufacturing method of an OLED panel, which comprises the following steps:

(1) providing a lid;

(2) coating a moisture-sensitive color change film on a circumferential edge of the lid, followed by low temperature baking, wherein the moisture-sensitive color change film is made by mixing a hygroscopically expandable polymeric substance in a metal compound salt;

(3) coating UV resin on the circumferential edge of the lid at a location outside the moisture-sensitive color change film to form an enclosing frame;

(4) providing a substrate, wherein the substrate comprises an OLED element formed thereon; and

(5) aligning and bonding the substrate and the lid together with the UV resin and solidifying the enclosing frame to complete the manufacture of the OLED panel.

Step (3) further comprises coating a liquid desiccant on the lid and inside the enclosing frame. The metal compound salt is composed of cobalt chloride, cobalt sulfate, copper sulfate, and cupric chloride. The substrate is an array substrate and the lid is made of glass.

The present invention further provides a method for inspecting packaging effectiveness, which comprises the following steps:

(1) providing an OLED panel, wherein the OLED panel comprises: a substrate, a lid arranged opposite to the substrate, an OLED element arranged on the substrate, a moisture-sensitive color change film arranged on the lid, and an enclosing frame bonding the substrate and the lid together, the substrate, the lid, and the enclosing frame collectively defining a sealed space therebetween, the OLED element and the moisture-sensitive color change film being hermetically enclosed in the sealed space, the moisture-sensitive color change film being made by mixing a hygroscopically expandable polymeric substance in a metal compound salt;

(2) visually inspecting change of color of the moisture-sensitive color change film to preliminarily determine packaging effectiveness; and

(3) providing a measurement device for measuring an infrared spectrum curve of the moisture-sensitive color change film and analyzing the infrared spectrum curve to precisely calculate the water content of the sealed space so as to accurately determine the packaging effectiveness.

The metal compound salt is composed of cobalt chloride, cobalt sulfate, copper sulfate, and cupric chloride. The substrate is an array substrate. The lid is made of glass. The enclosing frame is formed of frit or UV resin.

The measurement device comprises an infrared spectrophotometer.

The efficacy of the present invention is that the present invention provides an OLED panel and a manufacturing method thereof and a method for inspecting packaging effectiveness, which use a hygroscopically expandable polymeric substance mixed in a metal compound salt to make a moisture-sensitive color change film. Since the hygroscopically expandable polymeric substance has better water absorbability, the moisture-sensitive color change film can serve as a desiccant of a sealed space of an OLED panel to extend the lifespan of the OLED panel and also, a portion of the metal compounds of the metal compound salt may react with moisture to turn into hydrates, causing color change so as to allow for determining packaging effectiveness according to the color change of the moisture-sensitive color change film after absorption of moisture thereby enabling easy determination of failure of the packaging through visual inspection and also enabling accurate measurement of water content of the sealed space of the OLED panel by using an infrared spectrophotometer to accurately determine the packaging effectiveness. Further, a manufacturing process of an OLED panel that involves such an inspection method is simple and can be easily carried out.

For better understanding of the features and technical contents of the present invention, reference will be made to the following detailed description of the present invention and the attached drawings. However, the drawings are provided for the purposes of reference and illustration and are not intended to impose undue limitations to the present invention.

### BRIEF DESCRIPTION OF THE DRAWINGS

The technical solution, as well as beneficial advantages, of the present invention will be apparent from the following detailed description of an embodiment of the present invention, with reference to the attached drawings. In the drawings:

FIG. 1 is a schematic view showing the structure of a preferred embodiment of an OLED panel according to the present invention;

FIG. 2 is a schematic view showing the structure of another preferred embodiment of an OLED panel according to the present invention;

FIG. 3 is a flow chart illustrating a first embodiment of a manufacturing method of an OLED panel according to the present invention;

FIG. 4 is a flow chart illustrating a second embodiment of the manufacturing method of the OLED panel according to the present invention;

FIG. 5 is a flow chart illustrating a third embodiment of the manufacturing method of the OLED panel according to the present invention;

FIG. 6 is a flow chart illustrating a fourth embodiment of the manufacturing method of the OLED panel according to the present invention;

FIG. 7 is a flow chart illustrating a method for inspecting packaging effectiveness of an OLED panel according to the present invention.

### DETAILED DESCRIPTION OF THE PREFERRED EMBODIMENTS

To further expound the technical solution adopted in the present invention and the advantages thereof, a detailed description is given to a preferred embodiment of the present invention and the attached drawings.

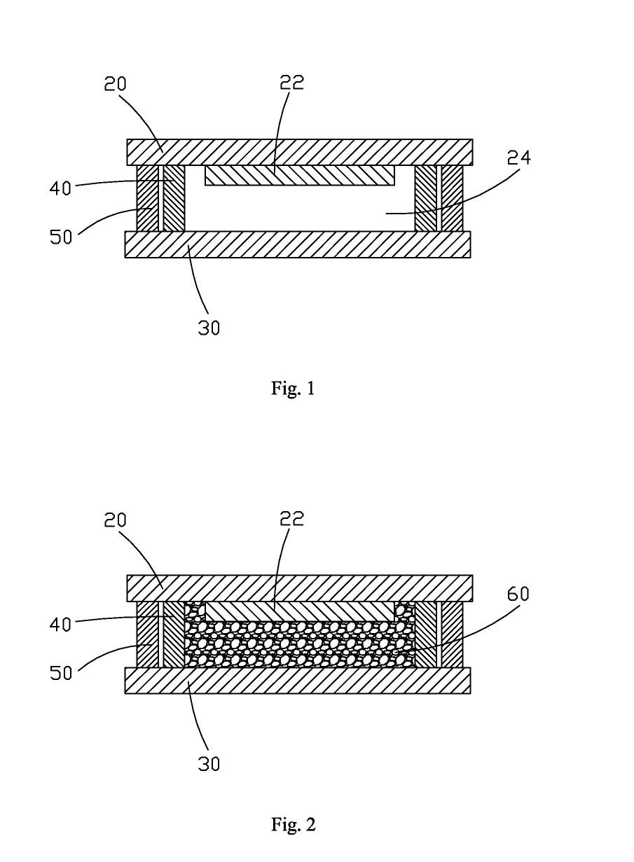

Referring to FIG. 1, the present invention provides an OLED (Organic Light Emitting Display) panel, which comprises: a substrate 20, a lid 30 arranged opposite to the substrate 20, an OLED element 22 arranged on the substrate 20, a moisture-sensitive color change film 40 arranged on the lid 30, and an enclosing frame 50 bonding the substrate 20 and the lid 30 together. The substrate 20, the lid 30, and the enclosing frame 50 collectively define a sealed space 24 therebetween. The OLED element 22 and the moisture-sensitive color change film 40 are hermetically enclosed in the sealed space 24. The moisture-sensitive color change film 40 is made by mixing a hygroscopically expandable polymeric substance in a metal compound salt.

The metal compound salt is composed of metal compounds, including cobalt chloride (CoCl₂), cobalt sulfate (CoSO₄), copper sulfate (CuSO₄), and cupric chloride (CuCl₂). The metal compound salt is susceptible to influence by moisture that penetrates into the sealed space 24 to have a portion of the metal compounds turned into hydrates (such as CuSO₄ turned into CuSO₄.5H₂O to change from white color to blue color), resulting in color change of the moisture-sensitive color change film 40. Inspection made with human eyes can preliminarily determine the packaging effectiveness of the OLED panel. The more the moisture that penetrates into the interior of the OLED panel is, the more the molecules of the metal compounds will be turned into hydrates. The variation of the substance would lead to a variation of absorption spectrum, so that a measurement device, such as an infrared spectrophotometer, can be used to measure an infrared spectrum curve. Through analysis of the infrared spectrum curve, the purposes of accurately measuring water contents inside the OLED panel can be achieved so as to calculate moisture penetration rate of the OLED panel for further determining the packaging effectiveness of the OLED panel. Thus, the moisture-sensitive color change film 40 that is made by mixing a hygroscopically expandable polymeric substance in metal compound salts can serve as a desiccant and can also serve as a reference basis for determining failure of the package of the OLED panel according to the color change thereof after absorption of moisture.

The OLED element 22 generally comprises: the anode, an organic layer formed on the anode, and a cathode formed on the organic layer. It is noted that the organic layer generally comprises a hole transport layer (HTL) formed on the anode, an emitting material layer (EML) formed on the hole transport layer, and an electron transport layer (ETL) formed on the emitting material layer, each of these layer being formed through vapor deposition.

The substrate 20 is an array substrate. The array substrate is made of a transparent material and is preferably made of glass. The lid 30 is made of a transparent material and is preferably made of glass.

The enclosing frame 50 is made of frit or UV resin.

Referring to FIG. 2, which shows another embodiment of the OLED panel according to the present invention, additional reference being had to FIG. 1, the instant embodiment is generally identical to that shown in FIG. 1 and a difference resides in that in the instant embodiment, the OLED panel further comprises a liquid desiccant 60 arranged in the sealed space 24 for further absorbing moisture entering the interior of the OLED panel in order to prevent the organic material inside the OLED panel from reacting with moisture and oxygen and thus extending the lifespan of the OLED panel.

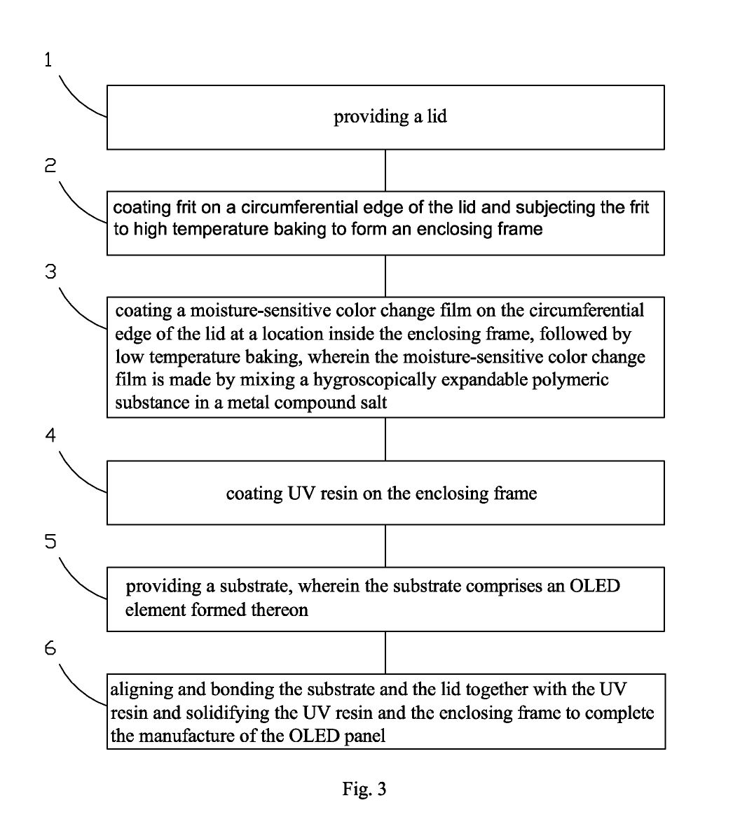

Referring to FIG. 3, which illustrates a first embodiment of a manufacturing method of an OLED panel according to the present invention, with additional reference being had to FIG. 1, the present invention also provides a manufacturing method of an OLED panel, which comprises the following steps:

Step 1: providing a lid 30.

The lid 30 is made of a transparent material and is preferably made of glass.

Step 2: coating frit on a circumferential edge of the lid 30 and subjecting the frit to high temperature baking to form an enclosing frame 50.

The frit is coated in such a way as to cover the circumferential edge of the lid 30 and is then subjected to high temperature baking to have the frit partially solidified to form the enclosing frame 50.

Step 3: coating a moisture-sensitive color change film 40 on the circumferential edge of the lid 30 at a location inside the enclosing frame 50, followed by low temperature baking, wherein the moisture-sensitive color change film 40 is made by mixing a hygroscopically expandable polymeric substance in a metal compound salt.

The metal compound salt is composed of metal compounds, including cobalt chloride (CoCl₂), cobalt sulfate (CoSO₄), copper sulfate (CuSO₄), and cupric chloride (CuCl₂). The metal compound salt is susceptible to influence by moisture that penetrates into the interior space of the OLED panel to have a portion of the metal compounds turned into hydrates (such as CuSO₄ turned into CuSO₄.5H₂O to change from white color to blue color), resulting in color change of the moisture-sensitive color change film 40. Inspection made with human eyes can preliminarily determine the packaging effectiveness of the OLED panel. The more the moisture that penetrates into the interior of the OLED panel, the more the molecules of the metal compounds will be turned into hydrates. The variation of the substance would lead to a variation of absorption spectrum, so that a measurement device, such as an infrared spectrophotometer, can be used to measure an infrared spectrum curve. Through analysis of the infrared spectrum curve, the purposes of accurately measuring water contents inside the OLED panel can be achieved so as to calculate moisture penetration rate of the OLED panel for further determining the packaging effectiveness of the OLED panel. Thus, the moisture-sensitive color change film 40 that is made by mixing a hygroscopically expandable polymeric substance in metal compound salts can serve as a desiccant and can also serve as a reference basis for determining failure of the package of the OLED panel according to the color change thereof after absorption of moisture.

It is noted that since the moisture-sensitive color change film 40 is sensitive to moisture, when the moisture-sensitive color change film 40 is formed, the lid 30 is subjected to low temperature baking to ensure dryness thereof.

Step 4: coating UV resin on the enclosing frame 50.

In the instant embodiment, a layer of UV resin is additionally coated on the enclosing frame 50 to enhance the effectiveness of sealing.

Step 5: providing a substrate 20, wherein the substrate 20 comprises an OLED element 22 formed thereon.

The substrate 20 is an array substrate. The array substrate is made of a transparent material and is preferably made of glass.

The OLED element 22 generally comprises: the anode, an organic layer formed on the anode, and a cathode formed on the organic layer. It is noted that the organic layer generally comprises a hole transport layer (HTL) formed on the anode, an emitting material layer (EML) formed on the hole transport layer, and an electron transport layer (ETL) formed on the emitting material layer, each of these layer being formed through vapor deposition.

Step 6: aligning and bonding the substrate 20 and the lid 30 together with the UV resin and solidifying the UV resin and the enclosing frame 50 to complete the manufacture of the OLED panel.

After the substrate 20 and the lid 30 are aligned and positioned over each other, ultraviolet light is applied to irradiate and thus cure the UV resin and then laser sealing is applied to solidify frit, namely solidifying the enclosing frame 50, so as to hermetically enclose the OLED element 22 and the moisture-sensitive color change film 40 in the sealed space 24 defined collectively by the substrate 20, the lid 30, and the enclosing frame 50 thereby completing the manufacture of the OLED panel.

The OLED panel manufactured with the method of the present invention has an extended lifespan and allows for effective inspection of the effectiveness of the packaging thereof to enhance product quality.

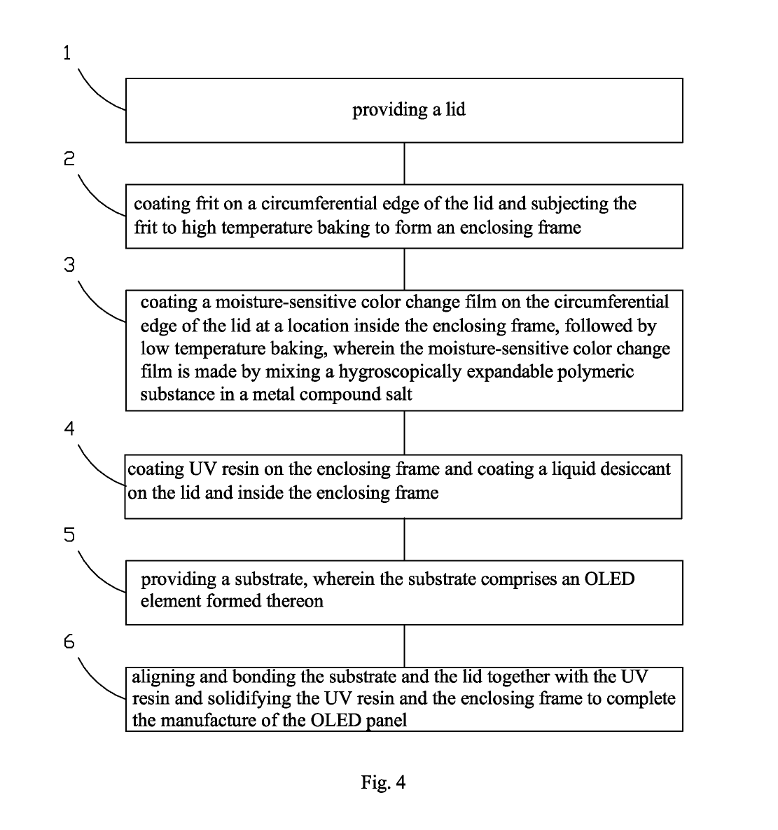

Referring to FIG. 4, which illustrates a second embodiment of a manufacturing method of an OLED panel according to the present invention, with additional reference being had to FIGS. 2 and 3, the instant embodiment is generally identical to that shown in FIG. 3 and a difference resides in that in the instant embodiment, Step 4 further comprises coating a liquid desiccant 60 on the lid 30 and inside the enclosing frame 50 to further absorb moisture entering the interior of the OLED panel in order to prevent the organic material inside the OLED panel from reacting with moisture and oxygen and thus extending the lifespan of the OLED panel.

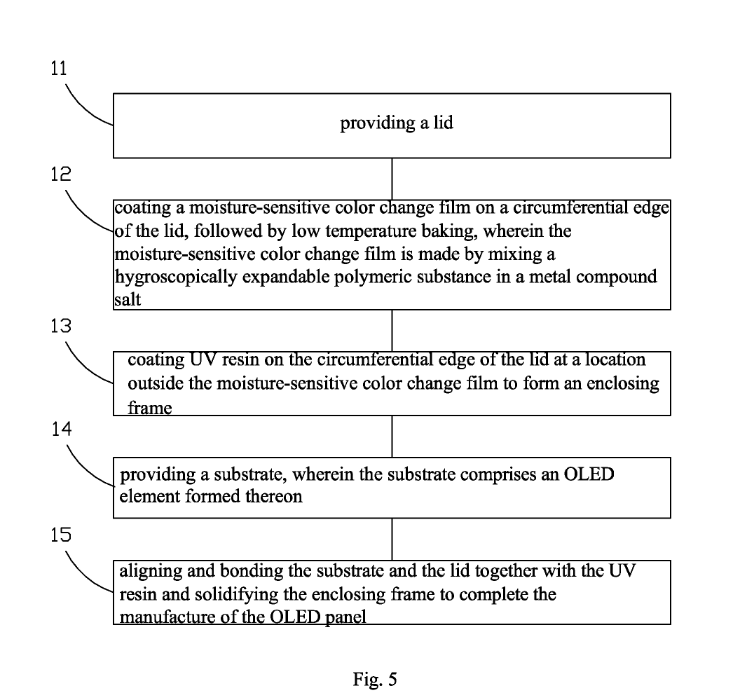

Referring to FIG. 5, which illustrates a third embodiment of a manufacturing method of an OLED panel according to the present invention, with additional reference being had to FIG. 1, the present invention also provides a manufacturing method of an OLED panel, which comprises the following steps:

Step 11: providing a lid 30.

The lid 30 is made of a transparent material and is preferably made of glass.

Step 12: coating a moisture-sensitive color change film 40 on a circumferential edge of the lid 30, followed by low temperature baking, wherein the moisture-sensitive color change film 40 is made by mixing a hygroscopically expandable polymeric substance in a metal compound salt.

The metal compound salt is composed of metal compounds, including cobalt chloride (CoCl₂), cobalt sulfate (CoSO₄), copper sulfate (CuSO₄), and cupric chloride (CuCl₂). The metal compound salt is susceptible to influence by moisture that penetrates into the interior space of the OLED panel to have a portion of the metal compounds turned into hydrates (such as CuSO₄ turned into CuSO₄.5H₂O to change from white color to blue color), resulting in color change of the moisture-sensitive color change film 40. Inspection made with human eyes can preliminarily determine the packaging effectiveness of the OLED panel. The more the moisture that penetrates into the interior of the OLED panel, the more the molecules of the metal compounds will be turned into hydrates. The variation of the substance would lead to a variation of absorption spectrum, so that a measurement device, such as an infrared spectrophotometer, can be used to measure an infrared spectrum curve. Through analysis of the infrared spectrum curve, the purposes of accurately measuring water contents inside the OLED panel can be achieved so as to calculate moisture penetration rate of the OLED panel for further determining the packaging effectiveness of the OLED panel. Thus, the moisture-sensitive color change film 40 that is made by mixing a hygroscopically expandable polymeric substance in metal compound salts can serve as a desiccant and can also serve as a reference basis for determining failure of the package of the OLED panel according to the color change thereof after absorption of moisture.

It is noted that since the moisture-sensitive color change film 40 is sensitive to moisture, when the moisture-sensitive color change film 40 is formed, the lid 30 is subjected to low temperature baking to ensure dryness thereof.

Step 13: coating UV resin on the circumferential edge of the lid 30 at a location outside the moisture-sensitive color change film 40 to form an enclosing frame 50.

In the instant embodiment, the enclosing frame 50 is formed of UV resin.

Step 14: providing a substrate 20, wherein the substrate 20 comprises an OLED element 22 formed thereon.

The substrate 20 is an array substrate. The array substrate is made of a transparent material and is preferably made of glass.

The OLED element 22 generally comprises: the anode, an organic layer formed on the anode, and a cathode formed on the organic layer. It is noted that the organic layer generally comprises a hole transport layer (HTL) formed on the anode, an emitting material layer (EML) formed on the hole transport layer, and an electron transport layer (ETL) formed on the emitting material layer, each of these layer being formed through vapor deposition.

Step 15: aligning and bonding the substrate 20 and the lid 30 together with the UV resin and solidifying the enclosing frame 50 to complete the manufacture of the OLED panel.

After the substrate 20 and the lid 30 are aligned and positioned over each other, ultraviolet light is applied to irradiate and thus cure the UV resin, so as to hermetically enclose the OLED element 22 and the moisture-sensitive color change film 40 in the sealed space 24 defined collectively by the substrate 20, the lid 30, and the enclosing frame 50 thereby completing the manufacture of the OLED panel.

The OLED panel manufactured with the method of the present invention has an extended lifespan and allows for effective inspection of the effectiveness of the packaging thereof to enhance product quality.

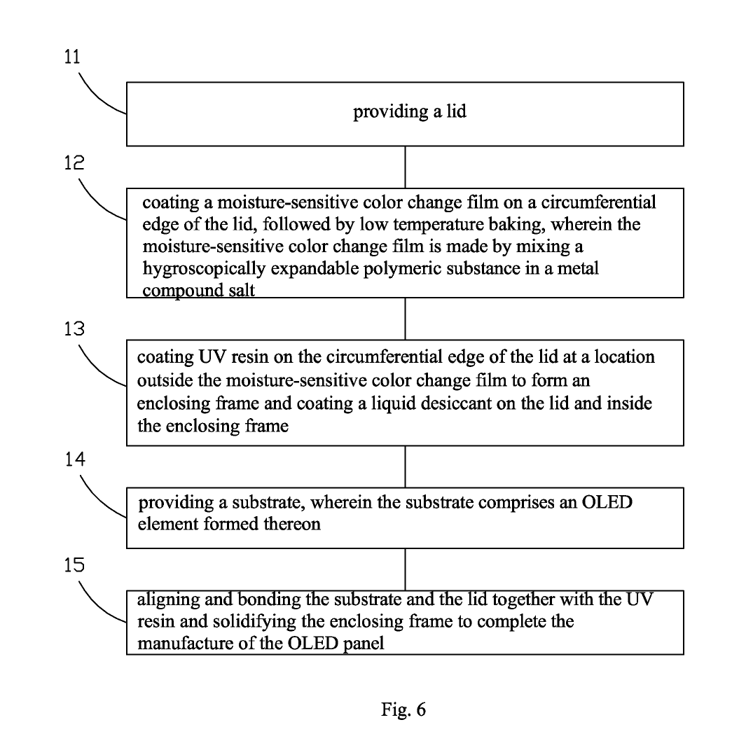

Referring to FIG. 6, which illustrates a fourth embodiment of a manufacturing method of an OLED panel according to the present invention, with additional reference being had to FIGS. 5 and 2, the instant embodiment is generally identical to that shown in FIG. 5 and a difference resides in that in the instant embodiment, Step 13 further comprises coating a liquid desiccant 60 on the lid 30 and inside the enclosing frame 50 to further absorb moisture entering the interior of the OLED panel in order to prevent the organic material inside the OLED panel from reacting with moisture and oxygen and thus extending the lifespan of the OLED panel.

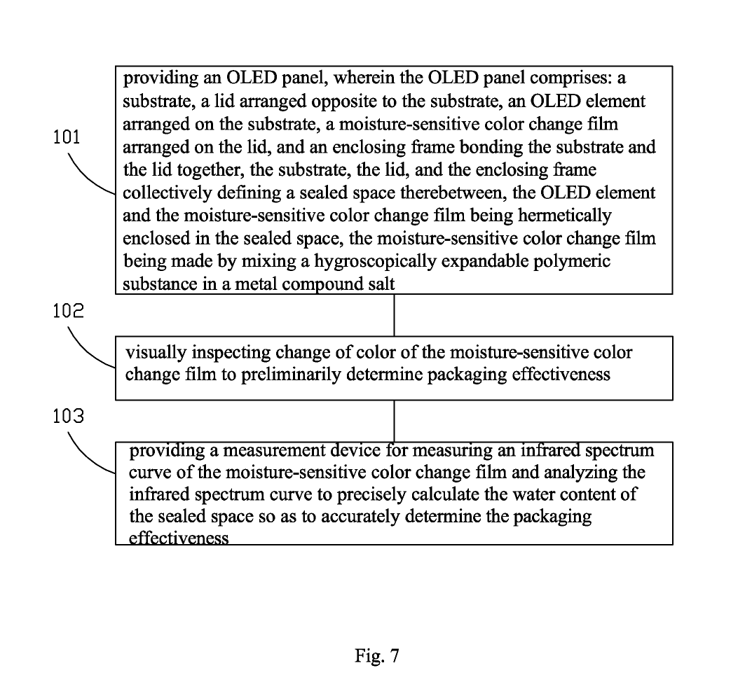

Referring to FIG. 7, the present invention further provides a method for inspecting packaging effectiveness, which comprises the following steps:

Step 101: providing an OLED panel, wherein the OLED panel comprises: a substrate 20, a lid 30 arranged opposite to the substrate 20, an OLED element 22 arranged on the substrate 20, a moisture-sensitive color change film 40 arranged on the lid 30, and an enclosing frame 50 bonding the substrate 20 and the lid 30 together. The substrate 20, the lid 30, and the enclosing frame 50 collectively define a sealed space 24 therebetween. The OLED element 22 and the moisture-sensitive color change film 40 are hermetically enclosed in the sealed space 24. The moisture-sensitive color change film 40 is made by mixing a hygroscopically expandable polymeric substance in a metal compound salt.

The substrate 20 is an array substrate. The array substrate is made of a transparent material and is preferably made of glass. The lid 30 is made of a transparent material and is preferably made of glass.

The OLED element 22 generally comprises: the anode, an organic layer formed on the anode, and a cathode formed on the organic layer. It is noted that the organic layer generally comprises a hole transport layer (HTL) formed on the anode, an emitting material layer (EML) formed on the hole transport layer, and an electron transport layer (ETL) formed on the emitting material layer, each of these layer being formed through vapor deposition.

The enclosing frame 50 is made of frit or UV resin.

The metal compound salt is composed of metal compounds, including cobalt chloride (CoCl₂), cobalt sulfate (CoSO₄), copper sulfate (CuSO₄), and cupric chloride (CuCl₂). The metal compound salt is susceptible to influence by moisture that penetrates into the sealed space 24 to have a portion of the metal compounds turned into hydrates (such as CuSO₄ turned into CuSO₄.5H₂O to change from white color to blue color), resulting in color change of the moisture-sensitive color change film 40, whereby it is possible to effectively determine if the packaging effectiveness of the OLED panel is good according to the change of color of the moisture-sensitive color change film 40.

Step 102: visually inspecting change of color of the moisture-sensitive color change film 40 to preliminarily determine packaging effectiveness.

The moisture-sensitive color change film 40 that is made by mixing a hygroscopically expandable polymeric substance in metal compound salts can serve as a desiccant and can also serve as a reference basis for determining failure of the package of the OLED panel according to the color change thereof after absorption of moisture.

The more the moisture penetrating into the interior of the sealed space 24 is, the more the moisture will be absorbed by the moisture-sensitive color change film 40 so that there will be more molecules of the metal compounds turned into hydrates, resulting in more apparent color change of the moisture-sensitive color change film 40, whereby inspection made with human eyes can preliminarily determine the packaging effectiveness of the OLED panel.

Step 103: providing a measurement device for measuring an infrared spectrum curve of the moisture-sensitive color change film 40 and analyzing the infrared spectrum curve to precisely calculate the water content of the sealed space 24 so as to accurately determine the packaging effectiveness.

The measurement device comprises an infrared spectrophotometer.

The change of a substance will result in a variation of the infrared absorption spectrum. In other words, there is a specific relationship between the infrared diffuse reflection spectrum and the molecular structure. Due to such a clear characteristic of the infrared diffuse reflection spectrum, it is possible to determine the spatial structure of molecule according to the absorption band and the location, intensity, and shape of wavelength of the infrared spectrum so as to determine molecular structure, achieving inspection of contents of substance. For example, taking qualitative inspection of water content in Chinese medicine by using the infrared diffuse reflection spectrum as an example. The primary frequency multiplication of the stretching vibration of OH group of water molecule is at around 1440 nm of near infrared zone, secondary frequency multiplication is at 960 nm, whereby the combined frequency absorption band is at 1940 nm, where the spectrum characteristic is very clear. When water content in the Chinese medicine is increased, with a scan range of 760 nm-2500 nm, all the wavelength point within the scan range may make the color of the Chinese medicine darkened due to the increase of water content and light absorbability increased, making an up shift of the entire infrared spectrum curve. By selecting one wavelength point of water characteristic absorption spectrum as an independent variable for multiple regression wavelength and also selecting another wavelength point that is irrelevant to water characteristic absorption spectrum, the difference of light absorption between the two wavelength points an be used to determine the water content in the Chinese medicine.

Since for the metal compound salt, after moisture penetrates into the interior of the sealed space 24, a portion of the metal compounds will turns into hydrates, so as to induce a variation of the infrared absorption spectrum of the moisture-sensitive color change film 40. Thus, the method for inspecting packaging effectiveness of an OLED panel according to the present invention allows for preliminary determination of the packaging effectiveness through visual inspection of the color change of the moisture-sensitive color change film 40 and also allows for measurement of the infrared spectrum curve of the moisture-sensitive color change film 40 by using a measurement device (such as an infrared spectrophotometer) so as to precisely calculate the water content inside the sealed space 24 by analysis of the curve thereby accurately calculating water penetration ratio of the sealed space 24 to accurately determine the packaging effectiveness.

The specific way is first establishing a function relationship y=f (x) through experiments, where the function relationship is a standard working curve of intensity variation of wavelength and water absorption of the moisture-sensitive color change film 40, in which y indicates intensity variation of a specific wavelength of the infrared spectrum curve and x indicates water. And, then, the height and width of the moisture-sensitive color change film 40 (which can be measured with the machine that coats the moisture-sensitive color change film 40) and the mixture ratios and densities of the metal compounds (which are presumably known) can be used to calculate the mass m (grams) of the metal compounds in the sealed space 24. Afterwards, a measurement device (such as an infrared spectrophotometer) is used to measure the infrared spectrum curve of the moisture-sensitive color change film 40 after absorption of water to obtain a specific value of intensity variation of the wavelength, which is divided by the mass m of the metal compounds to obtain the intensity variation y of the wavelength for each gram of the metal compounds. Then, y is compared with the standard working curve that is obtained through experiments to respect to obtain the water absorption x of each gram of the metal compounds x. Finally, the multiplication of the mass m of the metal compounds and the water absorption x of each gram of the metal compounds is the mass of moisture (gram) that penetrates into the sealed space 24. The mass of moisture is divided by the cross-sectional area of the enclosing frame that is in contact with air and is further divided by the time of measurement made under specific conditions of temperature and humidity to obtain the water penetration ratio of enclosing frame under specific conditions so as to correctly determine if the packaging effectiveness meets a prescribed value.

The method for inspecting packaging effectiveness is applicable to an OLED test panel and a final product panel and is also applicable to electronic components that require packaging, such as solar cell and liquid crystal display panel.

In summary, the present invention provides an OLED panel and a manufacturing method thereof and a method for inspecting packaging effectiveness, which use a hygroscopically expandable polymeric substance mixed in a metal compound salt to make a moisture-sensitive color change film. Since the hygroscopically expandable polymeric substance has better water absorbability, the moisture-sensitive color change film can serve as a desiccant of a sealed space of an OLED panel to extend the lifespan of the OLED panel and also, a portion of the metal compounds of the metal compound salt may react with moisture to turn into hydrates, causing color change so as to allow for determining packaging effectiveness according to the color change of the moisture-sensitive color change film after absorption of moisture thereby enabling easy determination of failure of the packaging through visual inspection and also enabling accurate measurement of water content of the sealed space of the OLED panel by using an infrared spectrophotometer to accurately determine the packaging effectiveness. Further, a manufacturing process of an OLED panel that involves such an inspection method is simple and can be easily carried out.

Based on the description given above, those having ordinary skills of the art may easily contemplate various changes and modifications of the technical solution and technical ideas of the present invention and all these changes and modifications are considered within the protection scope of right for the present invention.

1. An OLED (Organic Light Emitting Display) panel, comprising: a substrate, a lid arranged opposite to the substrate, an OLED element arranged on the substrate, a moisture-sensitive color change film arranged on the lid, and an enclosing frame bonding the substrate and the lid 30 together, wherein the substrate, the lid, and the enclosing frame collectively define a sealed space therebetween, the OLED element and the moisture-sensitive color change film being hermetically enclosed in the sealed space, the moisture-sensitive color change film being made by mixing a hygroscopically expandable polymeric substance in a metal compound salt.

2. The OLED panel as claimed in claim 1 further comprising a liquid desiccant arranged in the sealed space.

3. The OLED panel as claimed in claim 1, wherein the metal compound salt is composed of cobalt chloride, cobalt sulfate, copper sulfate, and cupric chloride, the substrate being an array substrate, the lid being made of glass, the enclosing frame being formed of frit or UV resin.

4. A manufacturing method of an OLED panel, comprising the following steps:
(1) providing a lid;
(2) coating frit on a circumferential edge of the lid and subjecting the frit to high temperature baking to form an enclosing frame;
(3) coating a moisture-sensitive color change film on the circumferential edge of the lid at a location inside the enclosing frame, followed by low temperature baking, wherein the moisture-sensitive color change film is made by mixing a hygroscopically expandable polymeric substance in a metal compound salt;
(4) coating UV resin on the enclosing frame;
(5) providing a substrate, wherein the substrate comprises an OLED element formed thereon; and
(6) aligning and bonding the substrate and the lid together with the UV resin and solidifying the UV resin and the enclosing frame to complete the manufacture of the OLED panel.

5. The manufacturing method of an OLED panel according to claim 4, wherein step (4) further comprises coating a liquid desiccant on the lid and inside the enclosing frame; the metal compound salt is composed of cobalt chloride, cobalt sulfate, copper sulfate, and cupric chloride; and the substrate is an array substrate and the lid is made of glass.

6. A manufacturing method of an OLED panel, comprising the following steps:
(1) providing a lid;
(2) coating a moisture-sensitive color change film on a circumferential edge of the lid, followed by low temperature baking, wherein the moisture-sensitive color change film is made by mixing a hygroscopically expandable polymeric substance in a metal compound salt;
(3) coating UV resin on the circumferential edge of the lid at a location outside the moisture-sensitive color change film to form an enclosing frame;
(4) providing a substrate, wherein the substrate comprises an OLED element formed thereon; and
(5) aligning and bonding the substrate and the lid together with the UV resin and solidifying the enclosing frame to complete the manufacture of the OLED panel.

7. The manufacturing method of an OLED panel as claimed in claim 6, wherein step (3) further comprises coating a liquid desiccant on the lid and inside the enclosing frame; the metal compound salt is composed of cobalt chloride, cobalt sulfate, copper sulfate, and cupric chloride; and the substrate is an array substrate and the lid is made of glass.

8. A method for inspecting packaging effectiveness, comprising the following steps:
(1) providing an OLED panel, wherein the OLED panel comprises: a substrate, a lid arranged opposite to the substrate, an OLED element arranged on the substrate, a moisture-sensitive color change film arranged on the lid, and an enclosing frame bonding the substrate and the lid together, the substrate, the lid, and the enclosing frame collectively defining a sealed space therebetween, the OLED element and the moisture-sensitive color change film being hermetically enclosed in the sealed space, the moisture-sensitive color change film being made by mixing a hygroscopically expandable polymeric substance in a metal compound salt;
(2) visually inspecting change of color of the moisture-sensitive color change film to preliminarily determine packaging effectiveness; and
(3) providing a measurement device for measuring an infrared spectrum curve of the moisture-sensitive color change film and analyzing the infrared spectrum curve to precisely calculate the water content of the sealed space so as to accurately determine the packaging effectiveness.

9. The method for inspecting packaging effectiveness as claimed in claim 8, wherein the metal compound salt is composed of cobalt chloride, cobalt sulfate, copper sulfate, and cupric chloride, the substrate being an array substrate, the lid being made of glass, the enclosing frame being formed of frit or UV resin.

10. The method for inspecting packaging effectiveness as claimed in claim 8, wherein the measurement device comprises an infrared spectrophotometer.
